(19) United States
(12) Patent Application Publication
(10) Pub. No.: US 2007/0241663 A1
(43) Pub. Date: Oct. 18, 2007

(54) Organic electroluminescent device

(75) Inventors: Chi-Hsien Huang, Chi-Lung City (TW); Pei-Hsun Yeh, Tai-Chung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Toppoly Optoelectronics Corp.

(21) Appl. No.: 11/402,442

(22) Filed: Apr. 12, 2006

(51) Int. Cl. H01L 51/52; H01L 51/54

(52) U.S. Cl. 313/503; 313/506; 428/690; 428/917; 257/E51.019

(57) ABSTRACT

An organic electroluminescent device includes an anode, an organic electroluminescent material layer, and a multi-layer transparent cathode on a substrate in sequence. The multi-layer transparent cathode has a thin metal layer in the bottom of the transparent cathode, a doped buffer layer on the thin metal layer, and a transparent electrode on the doped buffer layer.

### BACKGROUND OF THE INVENTION

1. Field of the Invention

The invention relates to an organic electroluminescent device, and more particularly, to an organic electroluminescent device with a buffer layer in the cathode.

2. Description of the Prior Art

In various types of flat panel displays, since an organic electroluminescent display (OLED) has many beneficial characteristics, such as having a spontaneous light source, a wide viewing angle, fast response time, full-color, simpler structure, and power savings, the OLED has been used extensively in small and medium scale portable display fields.

An OLED is composed of many organic electroluminescent devices that comprise organic electroluminescent materials. U.S. Pat. No. 6,548,956 has disclosed an organic electroluminescent device with vertically stacked layers of a dual emission color display. Referring to FIG. 1, FIG. 1 is a cross-sectional view of an organic electroluminescent device according to U.S. Pat. No. 6,548,956. The organic electroluminescent device 100 is grown on a glass substrate 102 pre-coated with a transparent indium tin oxide (ITO) thin film 104. The layer 106 includes hole conducting compound, and the layer 108 includes electron conducting and highly electroluminescent materials, wherein the layers 106, 108 are composed of organic materials. The layer 110 provides an electron injecting contact to the device 100, which is made by deposition and composed of metal material, including a thin semi-transparent Mg-Ag alloy electrode. The top layer 112 is a thick ITO or a thick indium zinc oxide (IZO). Numerals 114 and 116 represent electrode contacts. The ITO thin film 104 serves as an anode while the top layer 112 and the thin metal layer 110 serve as a cathode of the organic electroluminescent device 100.

For electron injection, the work function of the thin metal layer 110 has to match the lowest unoccupied molecular orbital (LUMO) energy level of the organic materials in the layer 108. On the other hand, since the organic electroluminescent device 100 is a dual emission color display, the top layer 112 and the thin metal layer 110 must be transparent. Accordingly, the thin metal layer 110 has to be very thin, which insulted in a bad conductivity. Therefore, the top layer with a transparent conductive material, ITO or IZO, is essential to compensate the conductivity of the cathode. However, the transparent top layer 112 formed with ITO or IZO is sputter-deposited onto the Mg-Ag alloy surface of the thin metal layer 110, which easily damages the thin metal layer 110 and the organic materials in the layers 106, 108 due to the electrons and ions bombardment during sputter process. The damage would result in lower light-emitting efficiency and lifetime of the organic electroluminescent devices. Therefore, one of the disadvantages of the above-mentioned disclose is that the light-emitting efficiency and lifetime of the organic electroluminescent devices are decreased.

Another disclosure of an organic electroluminescent device is disclosed in U.S. Pat. No. 6,420,031, Parthasarathy et al. FIG. 2 is a sectional-view of a transparent OLED (TOLED) 200 shown in the application of Parthasarathy et al. The TOLED includes a non-metallic cathode 202, an electron injecting interface layer (EIL) 204, an electron transporting layer (ETL) 206, a hole transporting layer (HTL) 208, an anode layer 210, and a substrate 212. After depositing the hole transporting layer 208 and the electron transporting layer 206, the electron injecting interface layer 204 is added by depositing a thin film of copper phthalocyanine (CuPc) which is then capped with a film of sputtered ITO. This ITO layer functions as the cathode 202 of the TOLED 200.

However, the CuPc material absorbs light with wavelength of about 625 nm which resulted in influence of light efficiency. In addition, the utilization of CuPc near the cathode leads to high operating voltages. Furthermore, the evaporation temperature of CuPc is much higher than other organic materials and it is hard to clean CuPc materials so that the evaporation chamber is easily contaminated during forming the CuPc layer. Accordingly, the TOLED 200 with CuPc material is not suitable for applying to mass production.

Accordingly, to provide an organic electroluminescent device with preferable light-emitting efficiency, easily fabricated in mass production, is still an important issue for manufactures.

### SUMMARY OF THE INVENTION

An electronic device comprising an organic electroluminescent device for displaying images is provided. An embodiment of such the organic electroluminescent device comprises an anode, an organic electroluminescent layer, and a multi-layer transparent cathode on a substrate in sequence. The transparent cathode comprises a thin metal layer in the bottom of the transparent cathode, a doped buffer layer on the thin metal layer, and a transparent electrode on the doped buffer layer.

The doped buffer layer provides a function of protecting the thin metal layer and the underlying and maintains the electron injection efficiency even when the materials of the transparent electrode have a high work function. Therefore, an embodiment of the present invention provides a top-emission or a dual emission OLED having the organic electroluminescent devices, which has preferable light-emitting efficiency and a long lifetime.

These and other aspects of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional view of an organic electroluminescent device according to the prior art.

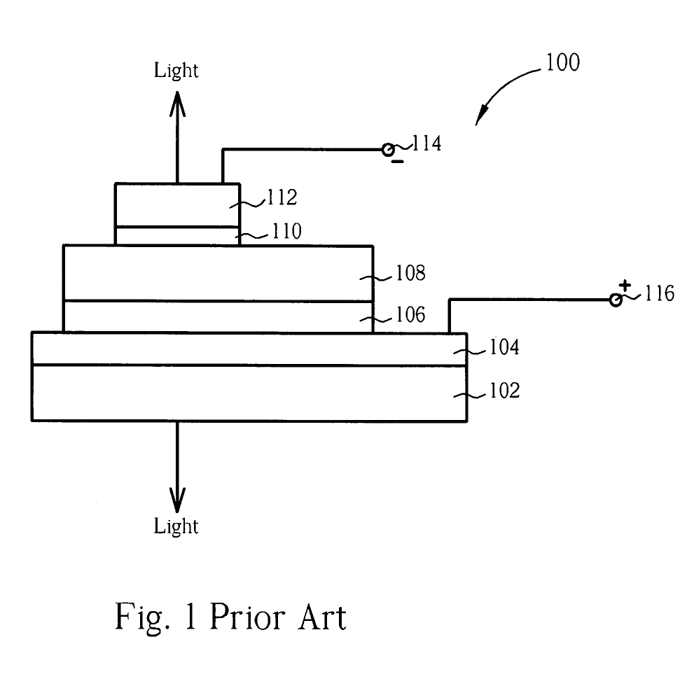

FIG. 2 is a sectional-view of a TOLED according to the prior art.

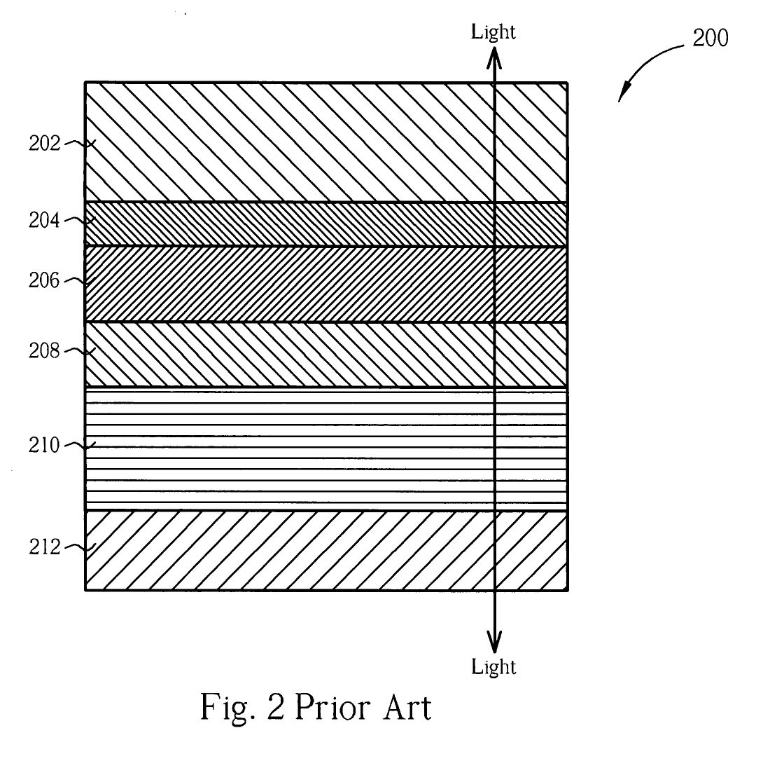

FIG. 3 is a top view of an electronic device for displaying images according to an embodiment of the present invention.

FIG. 4 is a sectional-view of the organic electroluminescent device shown in FIG. 3.

### DETAILED DESCRIPTION

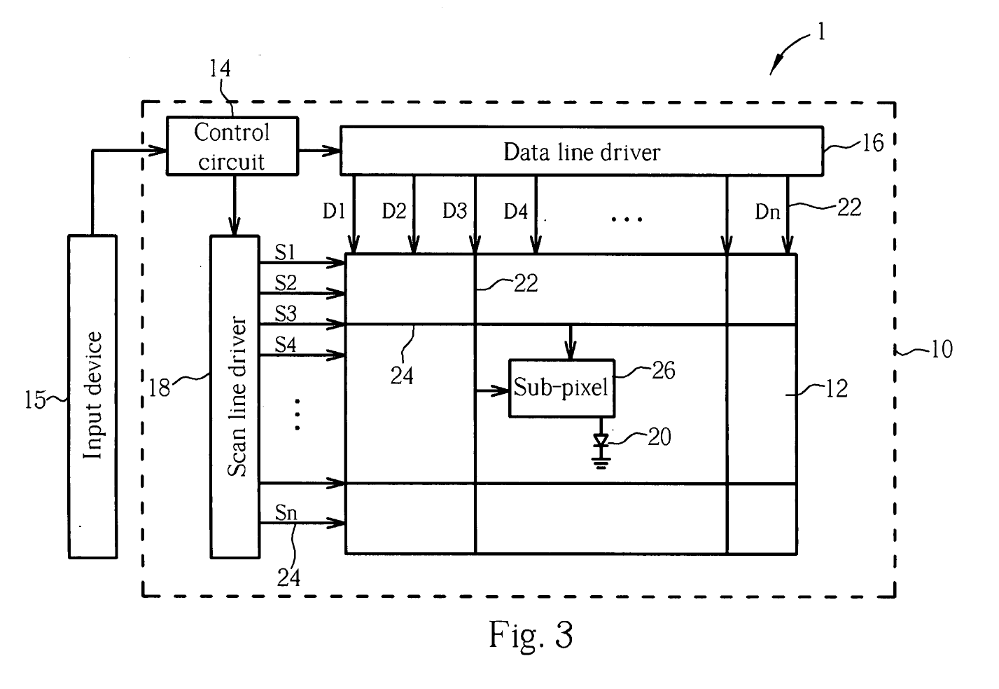

FIG. 3 is a top view of an electronic device for displaying images according to an embodiment of the present invention. As shown in FIG. 3, the electronic device 1 that comprises an input device 15 and an organic electroluminescent display (OLED) 10. The electronic device 1 may be a portable device such as a PDA, notebook computer, tablet computer, cellular phone, or a display monitor device, etc. Input device 15 can be coupled to the OLED 10. The input device 15 can include a processor or the like to provide image data to a control circuit 14 to render images. The OLED 10 comprises a display area 12 including a matrix composed of a plurality of data lines 22 (such as D1, D2, and D3) and scan lines 24 (such as S1, S2, and S3). The display area 12 also comprises a plurality of sub-pixel circuits 26, wherein each sub-pixel circuit 26 has at least one thin film transistor (TFT) and an organic electroluminescent device 20 at each intersection of a data line 22 and a scan line 24. Each sub-pixel circuit 26 is electrically connected to a corresponding data line 22 and a corresponding scan line 24 for driving the organic electroluminescent device 20 in the corresponding sub-pixel. The data lines D1, D2, and D3 connect to a data line driver 16 for receiving an image data signal, and the scan lines S1, S2, and S3 connect to a scan line driver 18 for receiving a switch/address signal. Both the scan line driver 18 and the data line driver 16 are controlled by a control circuit 14. The OLED 10 can be a top-emission display. However, the present invention can also be applied to a dual emission display.

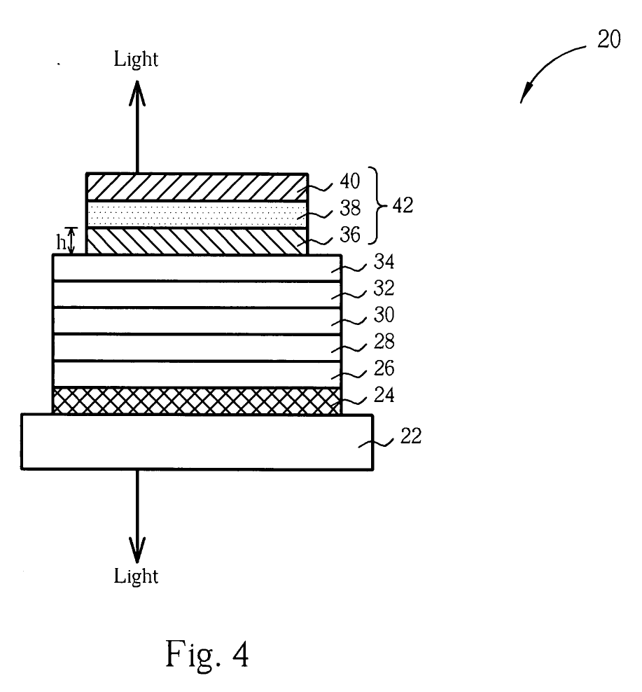

FIG. 4 is a sectional-view of the organic electroluminescent device 20 shown in FIG. 3. As shown in FIG. 4, the organic electroluminescent device 20 comprises a substrate 22 and an anode 24, a hole injection layer 26, a hole transport layer 28, an emitting layer 30, an electron transport layer 32, an electron injection layer 34, and a multi-layer transparent cathode 42 positioned on the substrate 22 in sequence. The OLED 10 can be a top emission display, wherein the substrate 22 and the anode electrode 24 can be both transparent. In this embodiment, the substrate 22 can be a glass substrate. According to various embodiments, the substrate can be plastic foil or metal foil. The anode 24 can be composed of ITO or IZO. However, in other embodiments, the anode 24 can be formed with aurum (Au), silver (Ag), aluminum (Al) or platinum (Pt) when it is not required to be transparent.

The hole injection layer 26, hole transporting layer 28, emitting layer 30, electron transporting layer 32, and electron injection layer 34 compose an organic electroluminescent material layer, and can be doped with materials of the emitting layer 30, wherein the concentration of the dopant is about 0.01%-10% by weight. The main materials of the hole injection layer 26 is LGC101®, produced by LG Chem. The material of the hole transporting layer 28 comprises 4,4′-bis[N-(1-naphthyl)-N-phenylamino]biphenyl (NPB). The emitting layer 30 comprises tris (8-quinolinato-N,08)-aluminum (Alq3) doped by 10-(2-benzothiazolyl)-2,3,6,7-tetrahydro-1,1,7,7,-tetramethyl-1-1-H,5H,11H-[1]BENZOPYRANO[6,7,8-ij]quionlizin-11-one (C545T). The electron transporting 32 comprises Alq3 while the electron injection layer 34 comprises lithium fluoride (LiF). The above-mentioned organic electroluminescent materials in each layer may be formed on the anode 24 by evaporation, spin coating or ink jet printing individually. According to various embodiments, the layers comprising the organic electroluminescent materials are formed by vacuum evaporation, evaporation on molecular beam epitaxy (MBE), dipping, spin coating, casting, bar code, and roll coating processes.

The multi-layer transparent cathode 42 is composed of a thin metal layer 36, a doped buffer layer 38, and a transparent electrode 40 from bottom to top. The thin metal layer 36 can be fabricated by an evaporation process, and selectively comprises aluminum (Al), silver (Ag), barium (Ba), calcium (Ca), magnesium (Mg)/Ag alloy, Al/Li alloy, Al/Ba alloy, or alloy of the above metal materials. For transmitting light, the thickness h of the thin metal layer 36 as shown in FIG. 4 can be less than or equal to 20 nm. In an embodiment, the thin metal layer can have a range of about 1 nm to 20 nm. The doped buffer layer 38 comprise electron transporting materials and doped with a low work function dopant, wherein the electron transporting materials can beAlq3 or bis (10-hydroxyben-zo[h]quinolinato) beryllium (Bebq2). The doped buffer layer 38 can be formed by a co-evaporation process. The dopant of the doped buffer layer 38 comprises metal materials with a low work function, wherein the low work function can be less than or equal to 4.2 electron volts (eV). In an embodiment, the metal materials of the dopant comprise alkali metals, alkali earth metals, transition metals, or rare earth metals. According to various embodiments, the metal materials of the dopant can selected from lithium (Li), cesium (Cs), strontium (Sr), or samarium (Sm). The dopant concentration of the metal materials in the doped buffer layer 38 can be about 0.1-99% by weight. In an embodiment, the dopant concentration can be 0.1-30% by weight. The thickness of the doped buffer layer 38 can be about 1 nm to 50 nm. After forming the doped buffer layer 38, a transparent electrode 40 can be formed by a sputter process, wherein the transparent electrode 40 comprises ITO or IZO and has a thickness of about 10 nm to 400 nm. The doped buffer layer 38 can prevent the thin metal layer 36 and the organic electroluminescent materials below the thin metal layer 36 from damages during the sputtering process for forming the transparent electrode 40. In addition, the electron transporting materials doped with low-work-function metals in the doped buffer layer 38 have high electron injection and transporting efficiency, thus the organic electroluminescent device 20 still has a high electron injection efficiency even though the materials of the transparent electrode 40 has a high work function.

According to various embodiments, the present invention provides an organic electroluminescent device with a doped buffer layer in its multi-layer transparent cathode. The organic electroluminescent device is capable of applying to an OLED or any electronic devices. With specific materials disclosed above, the doped buffer layer protects the thin metal layer and underlying organic materials without losing electron injection and transporting efficiencies, and the thin metal layer can be kept in the cathode layer for matching the LUMO energy level of the underlying organic materials so that the device has a preferable emitting efficiency. Therefore, a top-emission or a dual emission organic electroluminescent device or OLED with a long lifetime and preferable performance are provided according to the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An organic electroluminescent device comprising:
a substrate;
an anode on the substrate;
an organic electroluminescent material layer on the anode; and
a multi-layer transparent cathode on the organic electroluminescent layer, the transparent cathode comprising:
a thin metal layer in the bottom of the transparent cathode;
a doped buffer layer on the thin metal layer; and
a transparent electrode on the doped buffer layer.

2. The organic electroluminescent device as claimed in claim 1, wherein the doped buffer layer comprises electron transport materials.

3. The organic electroluminescent device as claimed in claim 2, wherein the doped buffer layer comprises tris(8-quinolinato-N1,08)-aluminum (Alq3) or bis(10-hydroxyben-zo[h]quinolinato) beryllium (Bebq2).

4. The organic electroluminescent device as claimed in claim 2, wherein the dopant of the doped buffer layer comprise metal materials.

5. The organic electroluminescent device as claimed in claim 4, wherein the metal materials have a work function of less than or equal to 4.2 electron volts (eV).

6. The organic electroluminescent device as claimed in claim 5, wherein the metal materials are selected from alkali metals, alkali earth metals, transition metals, or rare earth metals.

7. The organic electroluminescent device as claimed in claim 4, wherein the dopant of the doped buffer layer is selected from lithium (Li), cesium (Cs), strontium (Sr), or samarium (Sm).

8. The organic electroluminescent device as claimed in claim 4, wherein a dopant concentration of the doped buffer layer is about 0.1-99% by weight.

9. The organic electroluminescent device as claimed in claim 4, wherein a dopant concentration of the doped buffer layer is about 0.1-30% by weight.

10. The organic electroluminescent device as claimed in claim 1, wherein the doped buffer layer has a thickness of about 1 nm to 50 nm.

11. The organic electroluminescent device as claimed in claim 1, wherein the thin metal layer has a thickness of about 1 nm to 20 nm.

12. The organic electroluminescent device as claimed in claim 1, wherein the thin metal layer comprises aluminum (Al), silver (Ag), barium (Ba), calcium (Ca), magnesium (Mg)/Ag alloy, Al/Li alloy, or Al/Ba alloy.

13. The organic electroluminescent device as claimed in claim 1, wherein the transparent electrode has a thickness of about 10 nm to 400 nm.

14. The organic electroluminescent device as claimed in claim 1, wherein the transparent electrode comprises indium tin oxide (ITO) or indium zinc oxide (IZO).

15. The organic electroluminescent device as claimed in claim 1, wherein the organic electroluminescent material layer comprises:
a hole injection layer (HIL) on the anode;
a hole transporting layer (HTL) on the hole injection layer;
an emitting layer (EML) on the hole transporting layer;
an electron transporting layer (ETL) on the emitting layer; and
an electron injection layer (EIL) on the electron transporting layer.

16. The organic electroluminescent device as claimed in claim 1, wherein the organic electroluminescent device is a top emission device or a dual emission device.

17. The organic electroluminescent device as claimed in claim 1, wherein the substrate comprises glass, plastic foil or metal foil.

18. The organic electroluminescent device as claimed in claim 1, wherein the anode comprises ITO, IZO, aurum (Au), or platinum (Pt).

19. An organic electroluminescent display, comprising:
a display area comprising an organic electroluminescent device as claimed in claim 1;
a scan line driver and a data line driver coupled to the display area; and
a control circuit controlling the scan line driver and the data line driver to render images.

20. An electronic device, comprising:
an organic electroluminescent display as claimed in claim 19; and
a input device providing image data to the organic electroluminescent display to render images.
